(19) United States
(12) Patent Application Publication
(10) Pub. No.: US 2026/0293265 A1
(43) Pub. Date: Sep. 24, 2026

(54) DIELECTRIC LAYERS AROUND SEMICONDUCTOR NANOSTRUCTURES IN STACKED TRANSISTORS

(71) Applicant: Taiwan Semiconductor Manufacturing Co., Ltd., Hsinchu (TW)

(72) Inventors: Min-Chang Tsai, Tainan (TW); Tsung-Kai Chiu, Hsinchu (TW); Kai-Chieh Yang, New Taipei (TW)

(21) Appl. No.: 19/301,606

(22) Filed: Aug. 15, 2025

Related U.S. Application Data
(60) Provisional application No. 63/774,412, filed on Mar. 19, 2025.

(51) Int. Cl. H10D 64/27; H10D 84/01; H10D 84/83

(52) U.S. Cl. CPC H10D 64/516; H10D 84/0144; H10D 84/832

(57) ABSTRACT

A semiconductor device and the method of forming the same are provided. The semiconductor device may include a first epitaxial source/drain region, a first nanostructure on a sidewall of the first epitaxial source/drain region, and a first gate structure around the first nanostructure in a cross-sectional view. The first gate structure may include a first dielectric layer around the first nanostructure and a first gate electrode around the first dielectric layer in a cross-sectional view. A first portion of the first dielectric layer may be on a top surface of the first nanostructure and the first portion of the first dielectric layer may comprise a substantially flat top surface in the cross-sectional view. A second portion of the first dielectric layer may be on a bottom surface of the first nanostructure, and the second portion of the first dielectric layer may comprise a protruding bottom surface in the cross-sectional view.

### PRIORITY CLAIM AND CROSS-REFERENCE

This application claims the benefit of U.S. Provisional Application No. 63/774,412, filed on Mar. 19, 2025, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistor devices, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a stacking transistor device in accordance with some embodiments.

FIGS. 2, 3, 4, 5A, 5B, 6A, 6B 7A, 7B, 8A, 8B, 9A, 9B, 10A, 10B, 10C, 10D, 11A, 11B, 12A, 12B, 13A, 13B, 14A, 14B, 14C, 15A, 15B, 15C, 16A, 16B, 17A, and 17B are various views of intermediate stages in the manufacturing of a stacking transistor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. The semiconductor device may be a stacking transistor device comprising upper transistors and lower transistors that are vertically stacked. The upper transistors may include upper gate structures wrapping around upper semiconductor nanostructures and upper source/drain regions on sidewalls of the upper semiconductor nanostructures. The upper gate structures may include upper gate electrodes and upper gate dielectric layers. The lower transistors may include lower gate structures wrapping around lower semiconductor nanostructures and lower source/drain regions on sidewalls of the lower semiconductor nanostructures. The lower gate structures may include lower gate electrodes and lower gate dielectric layers. Sacrificial dielectric layers may be formed between neighboring upper semiconductor nanostructures. The sacrificial dielectric layers may reduce a risk of damaging the gate dielectric layers and a risk of having residual material of the lower gate electrodes between the neighboring upper semiconductor nanostructures during an etching process that recess the lower gate electrodes. As a result, the performance and reliability of the stacking transistor device may be improved.

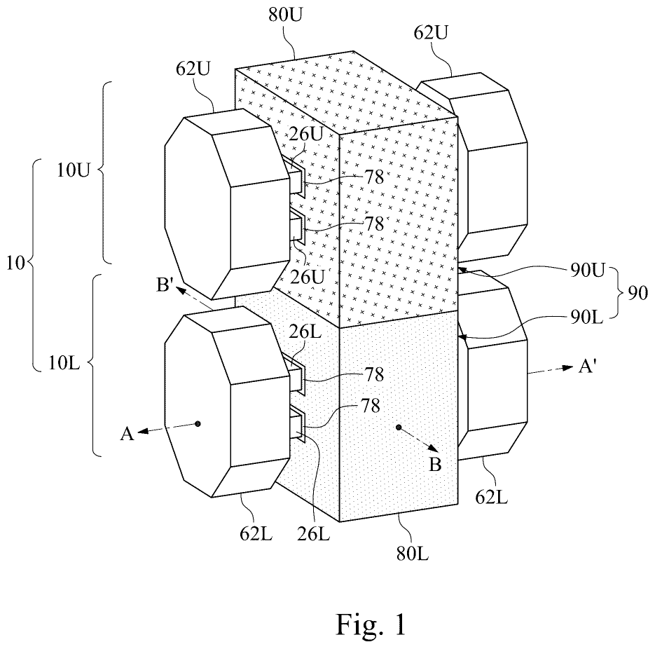

FIG. 1 illustrates an example of a stacking transistor device 10 in accordance with some embodiments. FIG. 1 is a perspective view, and some features of the stacking transistor device are omitted for illustration clarity. The stacking transistor device includes multiple vertically stacked FETs. For example, a stacking transistor device may include lower nanostructure-FETs 10L of a first device type (e.g., n-type or p-type) and upper nanostructure-FETs 10U of a second device type (e.g., p-type or n-type). When the stacking transistor device is a Complementary Field-Effect Transistors (CFET), the second device type of the upper nanostructure-FETs 10U is opposite to the first device type of the lower nanostructure-FETs 10L. The upper nanostructure-FETs 10U and lower nanostructure-FETs 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FETs 10L, and the upper semiconductor nanostructures 26U are for the upper nanostructure-FETs 10U. In other embodiments, the stacking transistor device may be applied to other types of transistors, Nano Field-effect Transistors (nano-FETs), Fin Field Effect Transistors (finFETs), or the like.

Gate dielectric layers 78 encircle the respective semiconductor nanostructures 26. Gate electrodes 80 (including lower gate electrode layers 80L and upper gate electrode layers 80U) are over the gate dielectric layers 78. Source/drain regions 62 (including lower epitaxial source/drain regions 62L and upper epitaxial source/drain regions 62U) are disposed on opposing sides of the gate dielectric layers 78 and the respective gate electrodes 80. Each of the source/drain regions 62 may refer to a source or a drain, individually or collectively dependent upon the context. Isolation features (not shown) may be formed to separate selected ones of the source/drain regions 62 and/or selected ones of the gate electrodes 80.

FIG. 1 further illustrates reference cross-section A-A′ and B-B′. Reference cross-section A-A′ may be a vertical cross-section that is parallel to a longitudinal axis of the semiconductor nanostructures 26 of the stacking transistor device 10 and in a direction of, for example, a current flow between the source/drain regions 62 of the stacking transistor device 10. Reference cross-section B-B′ may be a vertical cross-section that is perpendicular to the reference cross-section A-A′ and extend through the gate electrodes 80. The reference cross-sections A-A′ and B-B′ in FIG. 1 may correspond to the reference cross-sections A-A′ and B-B′ shown in some of the subsequent figures.

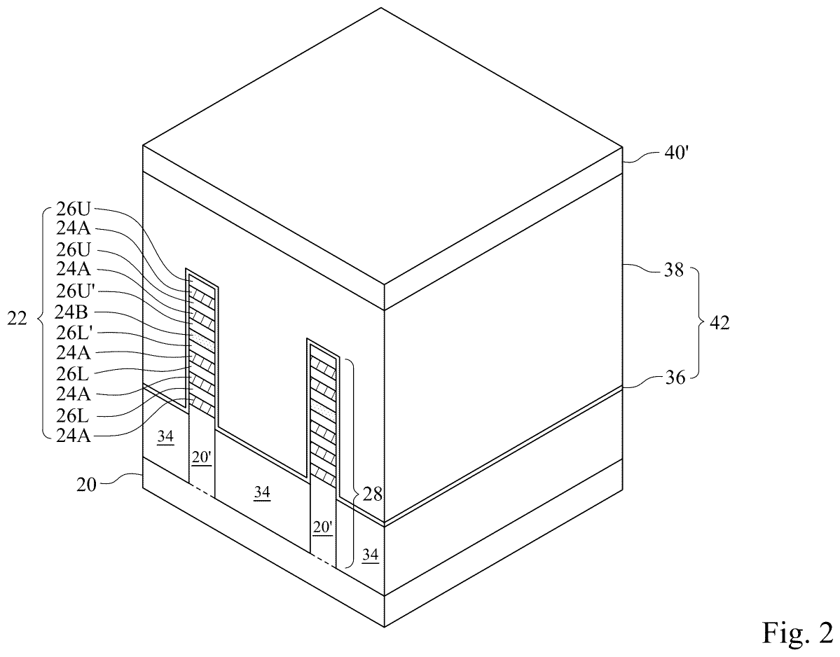

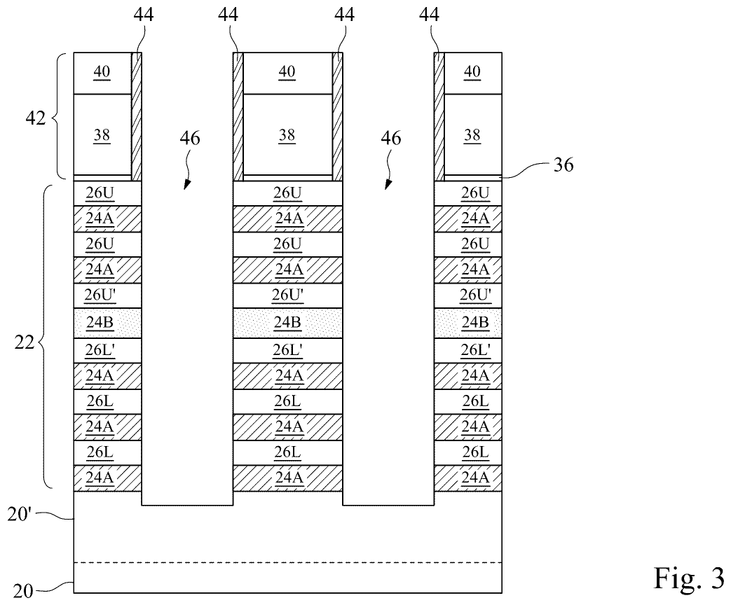

FIGS. 2 through 12B are various views of intermediate stages in the manufacturing of a stacking transistor device including lower nanostructure-FETs and upper nanostructure-FETs, which may be similar to the stacking transistor device 10 shown in FIG. 1, in accordance with some embodiments. FIG. 2 is a perspective view and FIGS. 3 through 17B are cross-sectional views of a portion of the structure shown in FIG. 2. In FIG. 2, a wafer, which includes substrate 20, is provided. The substrate 20 may be a semiconductor substrate formed of a crystalline semiconductor material. The substrate 20 may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor, the like, or combinations thereof.

Semiconductor strips 28 are formed extending upwards from the substrate 20. Each of semiconductor strips 28 includes semiconductor fin 20′ (patterned portions of the substrate 20) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, lower semiconductor nanostructures 26L′, upper semiconductor nanostructures 26U, and upper semiconductor nanostructures 26U′. The dummy nanostructures 24A and the dummy nanostructures 24B may further be collectively referred to as dummy nanostructures 24. The lower semiconductor nanostructures 26L, lower semiconductor nanostructures 26L′, upper semiconductor nanostructures 26U, and upper semiconductor nanostructures 26U′ may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent processes without significantly removing the semiconductor nanostructures 26. In some embodiments, the semiconductor nanostructures 26 are formed of silicon, the dummy nanostructures 24A are formed of silicon germanium, and the dummy nanostructures 24B are formed of germanium or silicon germanium with a higher germanium atomic percentage than the dummy nanostructures 24A.

The lower semiconductor nanostructures 26L may act as channel regions for lower nanostructure-FETs of the stacking transistor device. The upper semiconductor nanostructures 26U may act as channel regions for upper nanostructure-FETs of the stacking transistor device. The lower semiconductor nanostructures 26L′ and upper semiconductor nanostructures 26U′ that are immediately above/below (e.g., in contact with) the dummy nanostructures 24B may be used for isolation and may or may not act as channel regions for the stacking transistor device. FIG. 2 shows the upper nanostructure-FETs comprising two channel regions and the lower nanostructure-FETs comprising two channel regions as an example. The upper nanostructure-FETs may comprise one channel region, three channel regions, or other numbers of channel regions. The lower nanostructure-FETs may comprise one channel region, three channel regions, or other numbers of channel regions. The dummy nanostructures 24B may be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the substrate 20 to define the semiconductor strips 28, which includes the semiconductor fins 20′, the dummy nanostructures 24, and the semiconductor nanostructures 26.

For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the substrate 20. The etching may be performed by any acceptable etch process, such as a Reactive Ion Etch (RIE), Neutral Beam Etch (NBE), the like, or a combination thereof. The etching may be anisotropic.

STI regions 34 are formed over the substrate 20 and between adjacent semiconductor strips 28. The STI regions 34 may be on sidewalls of the semiconductor fins 20′. The STI regions 34 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 34 may include depositing the dielectric layer(s), and performing a planarization process such as a Chemical Mechanical Polishing (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 34 include silicon oxide formed by an FCVD process, followed by an anneal process. Then, the dielectric liner and the dielectric material are recessed to define the STI regions 34, such that upper portions of semiconductor strips 28 (including multi-layer stacks 22) protrude higher than the remaining STI regions 34.

After the STI regions 34 are formed, dummy gate stacks 42 may be formed over and along sidewalls of the upper portions of the semiconductor strips 28 (the portions that protrude higher than the STI regions 34). Forming the dummy gate stacks 42 may include forming dummy dielectric layers 36 on the semiconductor strips 28 and forming dummy gate layers 38 over the dummy dielectric layers 36. Dummy dielectric layers 36 may be formed of, for example, silicon oxide, silicon nitride, a combination thereof, or the like, and may be deposited or thermally grown according to acceptable techniques. The dummy gate layers 38 may be deposited, for example, through Physical Vapor Deposition (PVD), CVD, or other techniques, and then planarized, such as by a CMP process. The material of dummy gate layers 38 may be selected from a group including amorphous silicon, polycrystalline-silicon (polysilicon), poly-crystalline silicon-germanium (poly-SiGe), or the like.

A mask layer 40′ is formed over the planarized dummy gate layers 38. The mask layer 40′ may comprise, silicon nitride, silicon oxynitride, or the like. Then the mask layer 40′ may be patterned by suitable photolithography and etching processes to form a mask 40 (shown FIG. 3), which may be then used to pattern dummy gate layers 38 and the dummy dielectric layers 36. The mask 40, the remaining portions of the dummy gate layers 38, and the dummy dielectric layers 36 may be referred to as the dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. The mask 40, and the gate spacers 44 may be used to protect the dummy gate layers 38 during subsequent etching processes.

Subsequently, source/drain recesses 46 are formed in semiconductor strips 28. The source/drain recesses 46 are formed through etching, and may extend through the multi-layer stacks 22 and into the semiconductor fins 20′. The bottom surfaces of the source/drain recesses 46 may be at a level above, below, or level with the top surfaces of the STI regions 34 (not shown). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a selected depth.

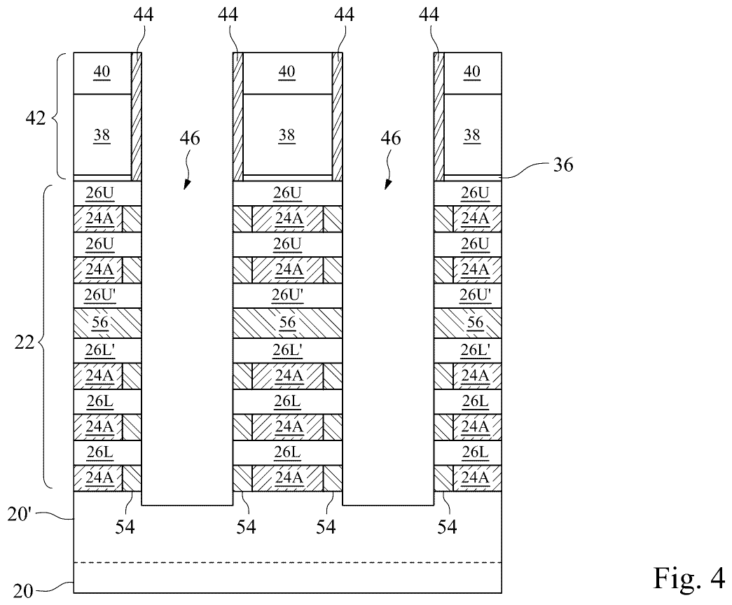

In FIG. 4, the dummy nanostructures 24A are partially removed and the dummy nanostructure 24B are completely removed. Then inner spacers 54 and dielectric isolation layers 56 are formed. After the dummy nanostructures 24A are partially removed, sidewalls of the dummy nanostructures 24A may be recessed. The dummy nanostructures 24A and the dummy nanostructure 24B may be removed by a suitable etching process. The etching process may selectively remove the materials of the dummy nanostructures 24A and the dummy nanostructure 24B without significantly removing the materials of the upper semiconductor nanostructures 26U and 26U′, the lower semiconductor nanostructures 26L and 26L′, or the semiconductor fins 20′. The etching process may remove the dummy nanostructures 24A at a slower rate than the dummy nanostructure 24B.

In the embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etching process may be a dry etching process using etchant(s), such as chlorine, and/or the like. Because the dummy gate stacks 42 wrap around the sidewalls of the semiconductor nanostructures 26 (see FIG. 2), the dummy gate stacks 42 may support the upper semiconductor nanostructures 26U and 26U′ so that the upper semiconductor nanostructures 26U and 26U′ do not collapse upon the complete removal of the dummy nanostructures 24B.

The inner spacers 54 may be formed on the recessed sidewalls of the dummy nanostructures 24A. The dielectric isolation layers 56 may be formed in spaces the dummy nanostructures 24B occupied before being removed. Source/drain regions may be subsequently formed in the source/drain recesses 46, and the dummy nanostructures 24A may be replaced with corresponding gate structures. The inner spacers 54 may be used to isolate the subsequently formed source/drain regions from the subsequently formed gate structures. The dielectric isolation layers 56 may be used to isolate the upper semiconductor nanostructures 26U and 26U′ from the lower semiconductor nanostructures 26L and 26L′.

The inner spacers 54 and the dielectric isolation layers 56 may be formed by conformally depositing a suitable dielectric material in the source/drain recesses 46, on the sidewalls the dummy nanostructures 24A, and between the upper semiconductor nanostructures 26U′ and the lower semiconductor nanostructures 26L′. The dielectric material may be then etched to remove excess portions. The dielectric material may be a hard dielectric material, such as a carbon-containing dielectric material, such as silicon oxycarbonitride, silicon oxycarbide, silicon carbonitride, or the like. Other low-dielectric constant (low-k) materials having a k-value less than about 3.5 may be utilized. The dielectric material may be formed by a suitable deposition process, such as ALD, CVD, or the like. The etching of the dielectric material may be an anisotropic etching process or an isotropic etching process.

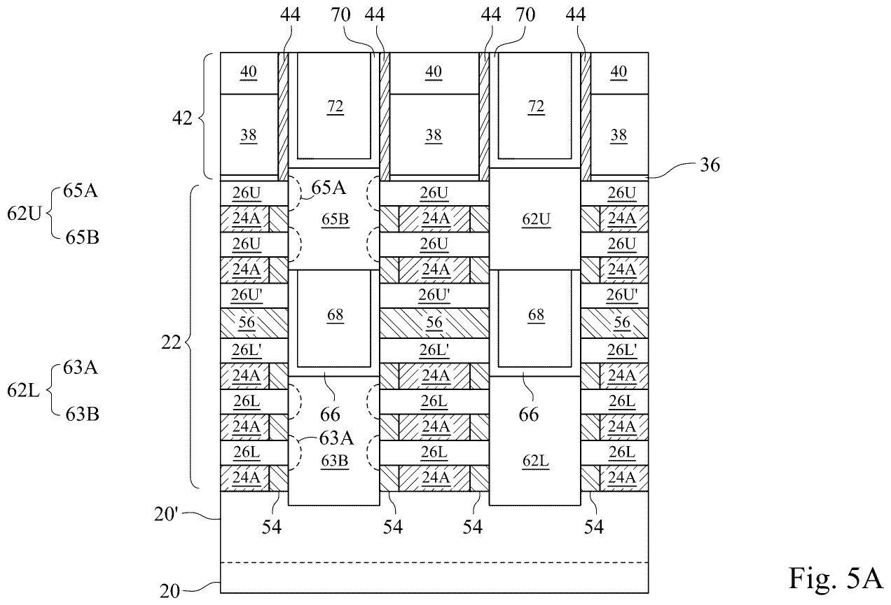

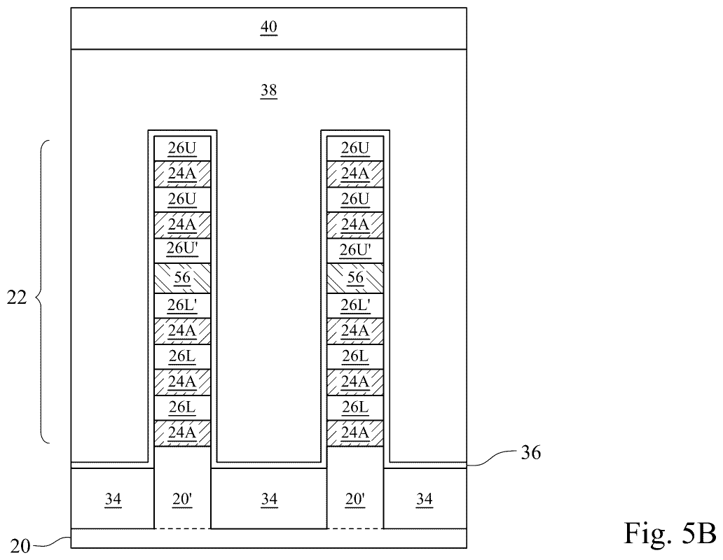

In FIGS. 5A and 5B, lower source/drain regions 62L, upper epitaxial source/drain regions 62U, first contact etch stop layers (CESLs) 66, first inter-layer dielectrics (ILDs) 68, second CESLs 70, and second ILDs 72 are formed in the source/drain recesses 46. FIG. 5A may be obtained along a reference cross-section corresponding to the reference cross-section A-A′ shown in FIG. 1 and FIG. 5B may be obtained along a reference cross-section that correspond to the reference cross-section B-B′ as shown in FIG. 1.

The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The upper epitaxial source/drain regions 62U are in contact with the upper semiconductor nanostructures 26U and are not in contact with the lower semiconductor nanostructures 26L. The lower epitaxial source/drain regions 62L are in contact with the inner spacers 54, which electrically insulate the lower epitaxial source/drain regions 62L from the dummy nanostructures 24A. The upper epitaxial source/drain regions 62U are in contact with inner spacers 54, which electrically insulate the upper epitaxial source/drain regions 62U from the dummy nanostructures 24A. The dummy nanostructures 24A will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U and 26U′ (e.g., sidewalls) may be masked to prevent undesired epitaxial growth on the upper semiconductor nanostructures 26U and 26U′. After the lower epitaxial source/drain regions 62L are grown, the masks on the upper semiconductor nanostructures 26U and 26U′ may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22 (not shown). In some embodiments, adjacent lower epitaxial source/drain regions 62L remain separated after the epitaxy process is completed. In other embodiments, these facets cause neighboring lower epitaxial source/drain regions 62L to merge. The lower epitaxial source/drain regions 62L may comprise one or more semiconductor material layers. In some embodiments, the lower epitaxial source/drain regions 62L, comprise first layers 63A in contact with (e.g., on, adjacent) the sidewalls of the lower semiconductor nanostructures 26L, and second layers 63B on the first layers 63A. The second layers 63B may be spaced apart (e.g., separated, away) from the lower semiconductor nanostructures 26L by the first layers 63A. The first layers 63A and the second layers 63B may be doped by a same dopant to different dopant concentrations.

The first CESLs 66 and the first ILDs 68 are formed over the lower epitaxial source/drain regions 62L. The first CESLs 66 may be formed of a dielectric material having a high etching selectivity from the etching of the first ILDs 68, such as silicon nitride, silicon oxide, silicon oxynitride, or the like, which may be formed by any suitable deposition process, such as CVD, ALD, or the like. The first ILDs 68 may be formed of a dielectric material, which may be deposited by any suitable method, such as CVD, plasma-enhanced CVD (PECVD), or FCVD. The applicable dielectric material of the first ILDs 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILDs 68, followed by a planarization process and then an etch-back process. In some embodiments, the first ILDs 68 are etched first, leaving the conformal CESL layer unetched. An anisotropic etching process is then performed to remove the portions of the conformal CESL layer higher than the recessed first ILDs 68. After the recessing, the sidewalls of the upper semiconductor nanostructures 26U and 26U′ are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U and 26U′. The materials of upper epitaxial source/drain regions 62U may be selected from the same candidate group of materials for forming lower epitaxial source/drain regions 62L, depending on the selected conductivity type of upper epitaxial source/drain regions 62U. The conductivity type of the upper epitaxial source/drain regions 62U may be opposite the conductivity type of the lower epitaxial source/drain regions 62L in embodiments where the stacking transistor device is a CFET. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant.

As a result of the epitaxy processes used for forming the upper epitaxial source/drain regions 62U, upper surfaces of the upper epitaxial source/drain regions 62U have facets which expand laterally outward beyond sidewalls of the multi-layer stacks 22 (not shown). In some embodiments, adjacent upper epitaxial source/drain regions 62U remain separated after the epitaxy process is completed. In other embodiments, these facets cause neighboring upper epitaxial source/drain regions 62U to merge. The upper epitaxial source/drain regions 62U may comprise one or more semiconductor material layers. In some embodiments, the upper epitaxial source/drain regions 62U, comprise first layers 65A in contact with (e.g., on, adjacent) the sidewalls of the upper semiconductor nanostructures 26U, and second layers 65B on the first layers 65A. The second layers 65B may be spaced apart (e.g., separated, away) from the upper semiconductor nanostructures 26U by the first layers 65A. The first layers 65A and the second layers 65B may be doped by a same dopant to different dopant concentrations.

After the upper epitaxial source/drain regions 62U are formed, second CESLs 70 and second ILDs 72 are formed. The materials and the formation methods may be similar to the materials and the formation methods of the first CESLs 66 and the first ILDs 68, respectively. The formation process may include depositing the conformal CESL layer and the second ILDs 72, and performing a planarization process to remove the excess portion of the corresponding layers. After the planarization process, top surfaces of the second ILDs 72, the gate spacers 44, and the mask 40 are substantially coplanar (within process variations). In the illustrated embodiment, the mask 40 remain after the removal process. In other embodiments, the mask 40 are removed such that the top surfaces of the dummy gate layers 38 are exposed.

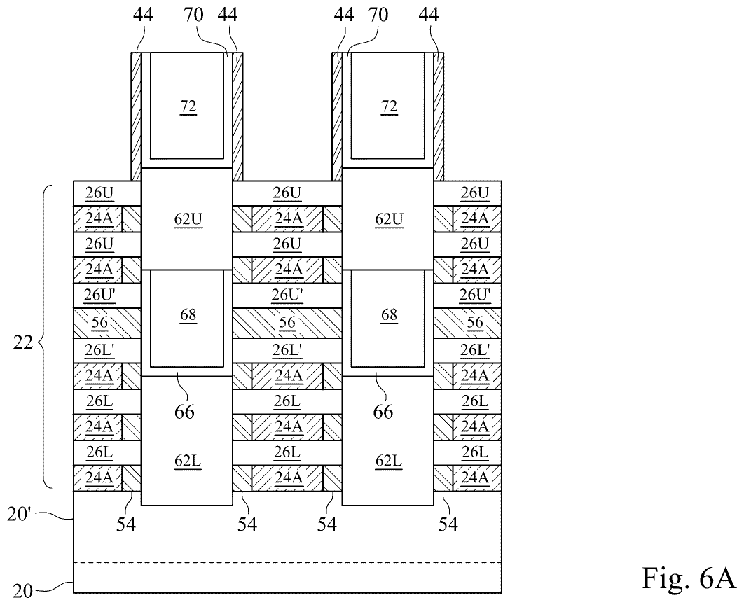

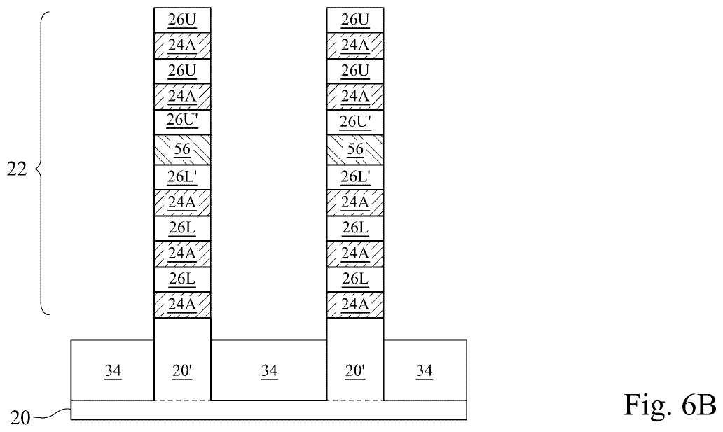

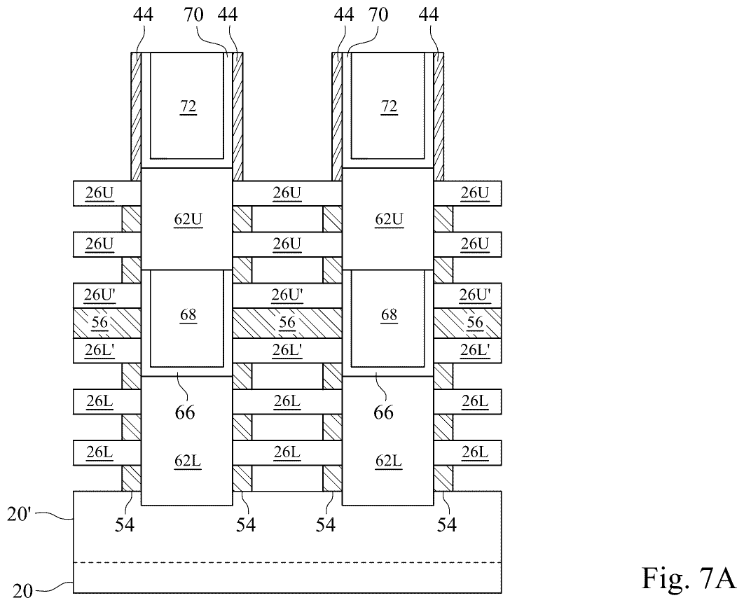

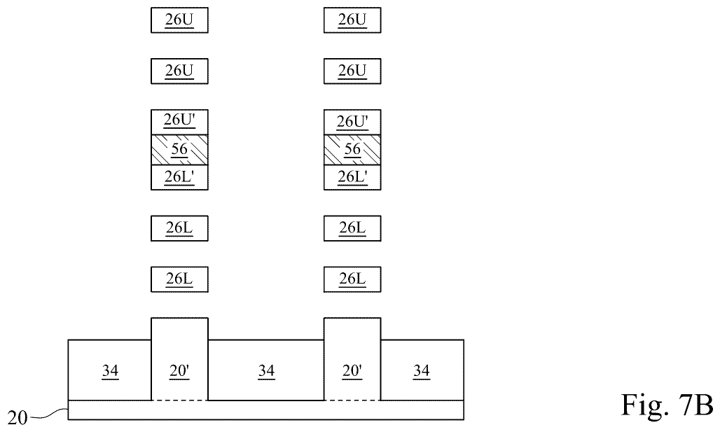

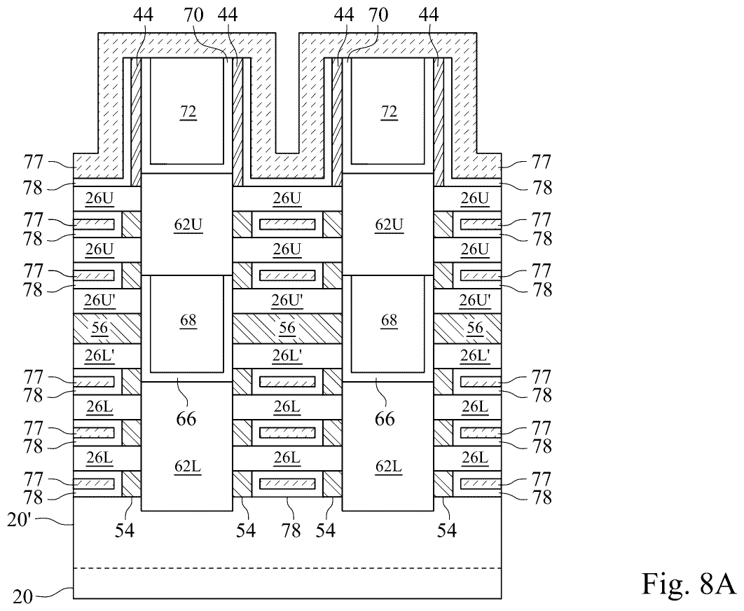

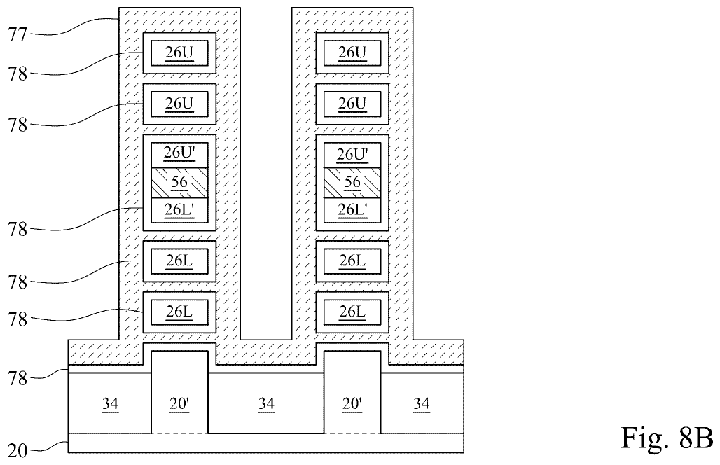

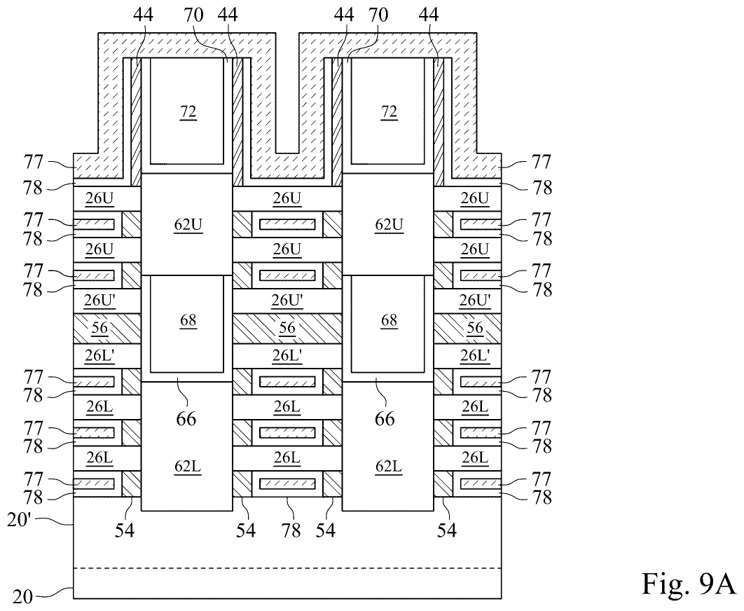

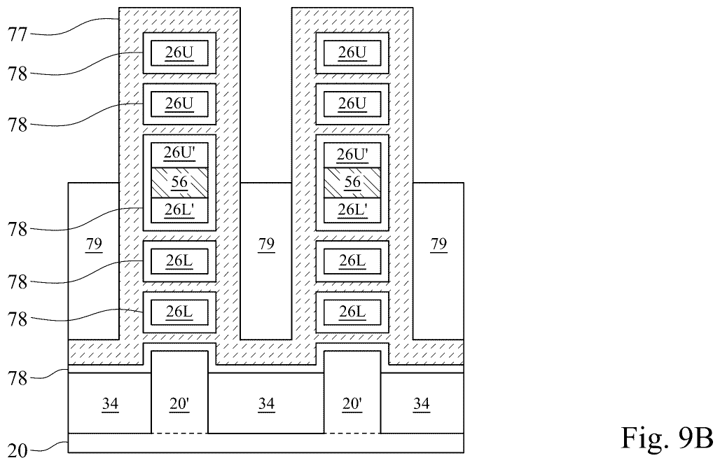

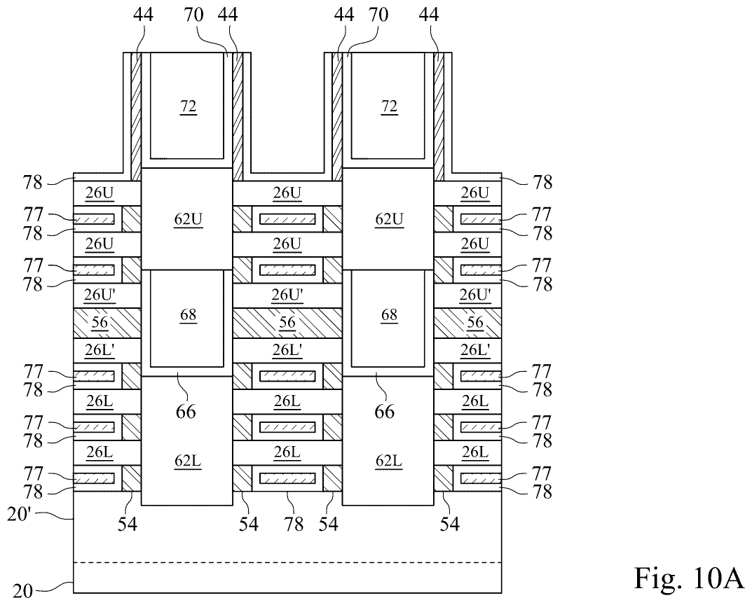

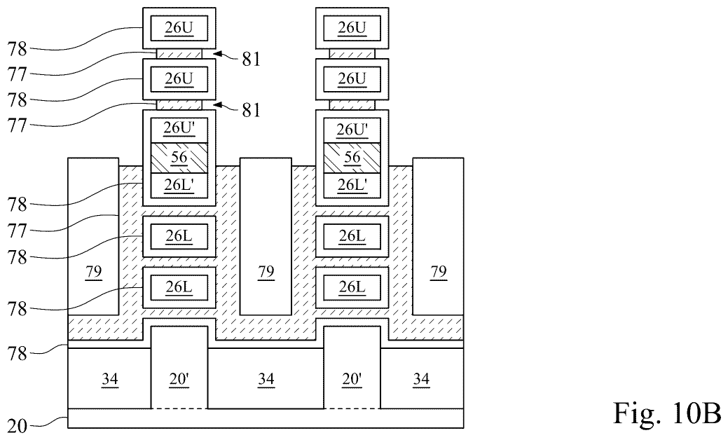

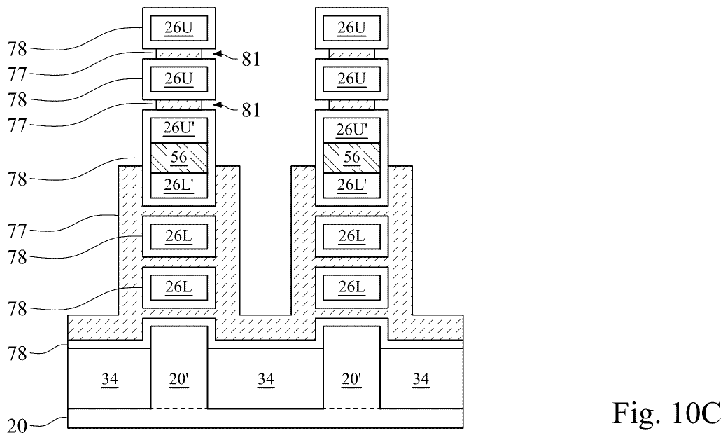

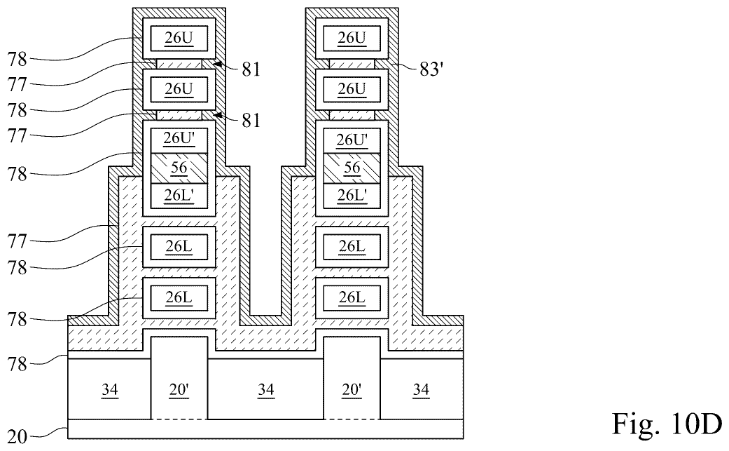

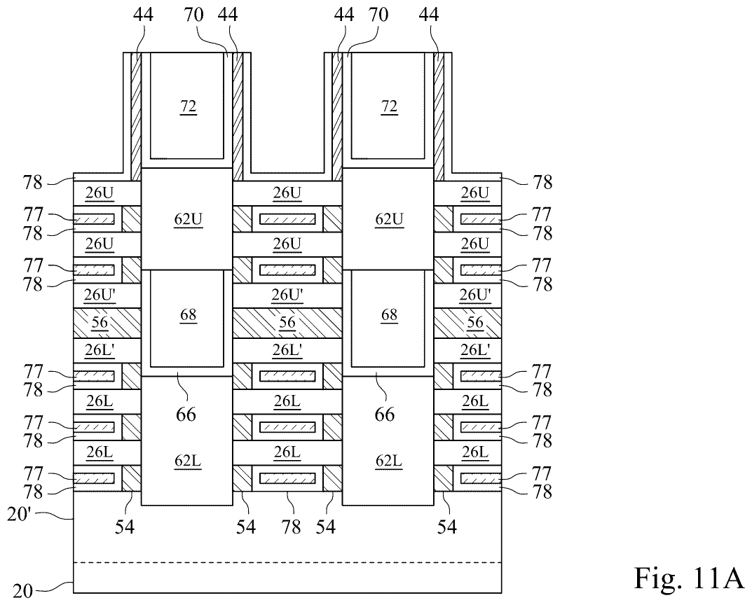

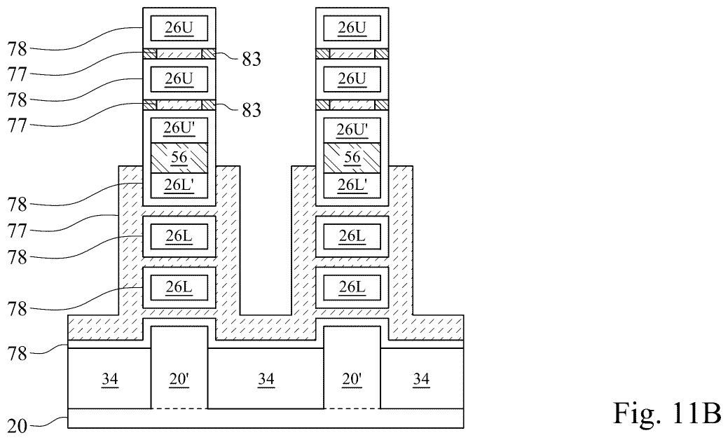

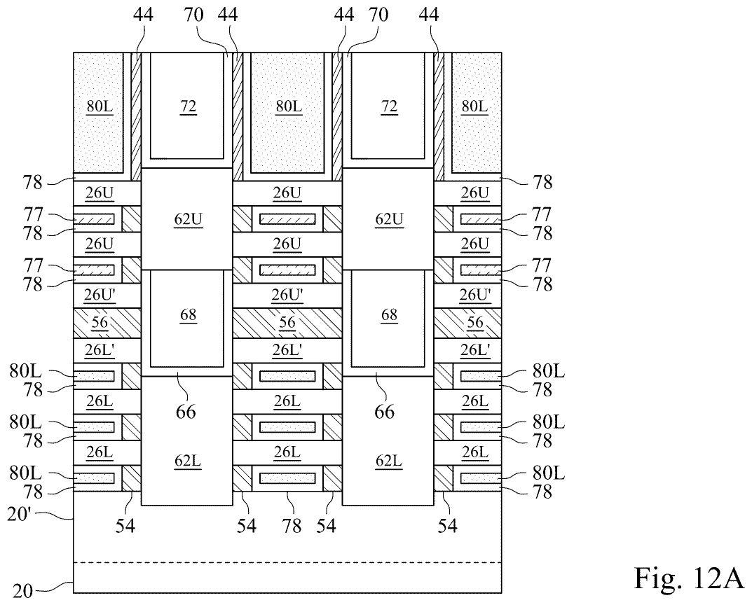

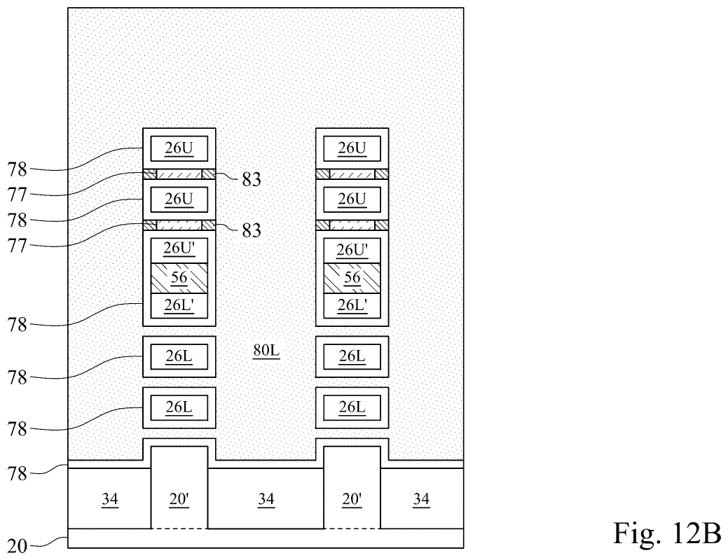

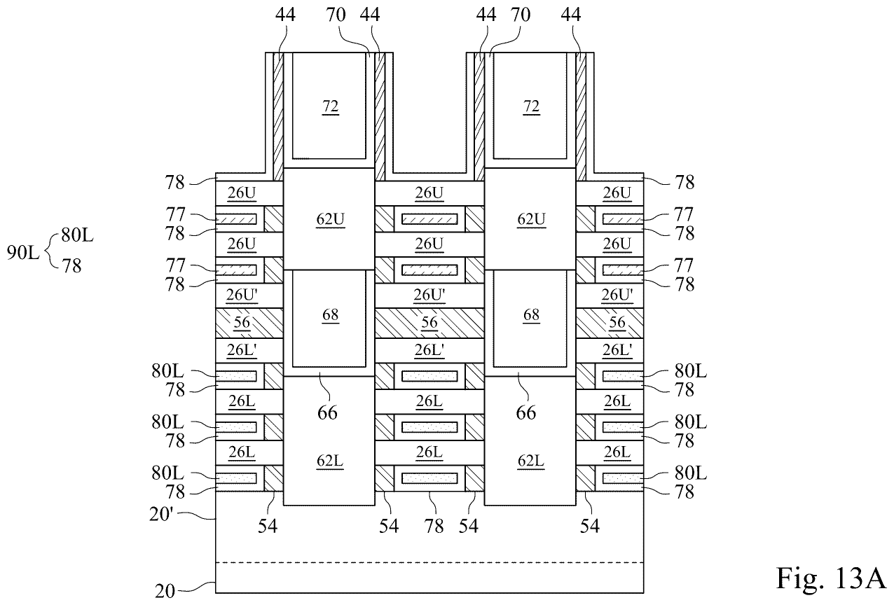

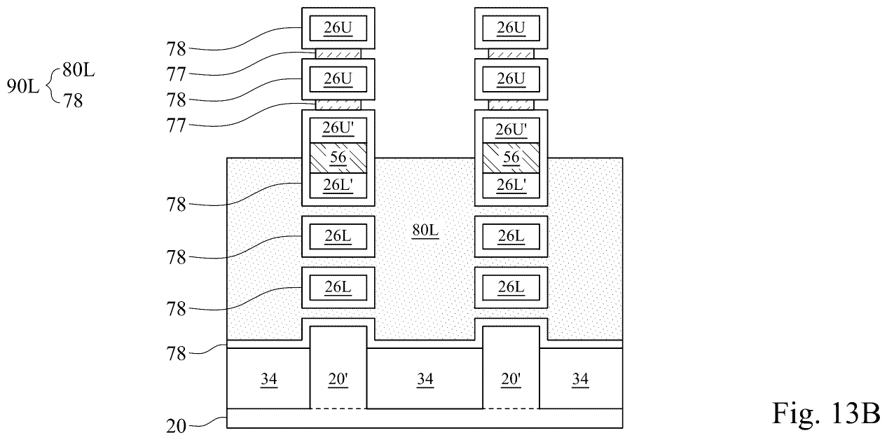

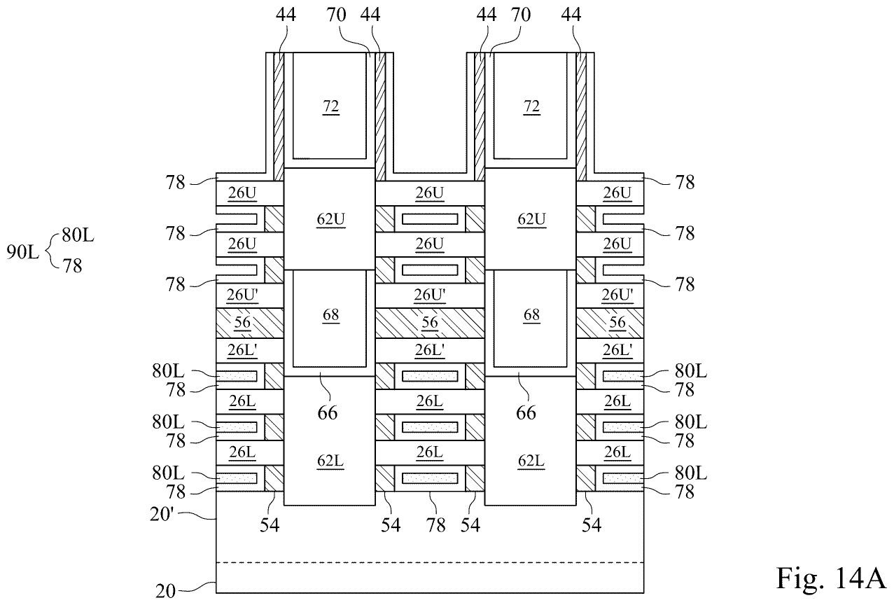

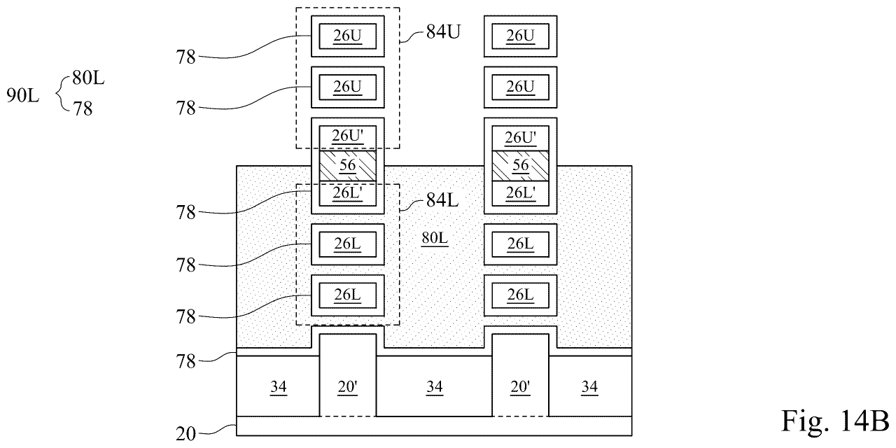

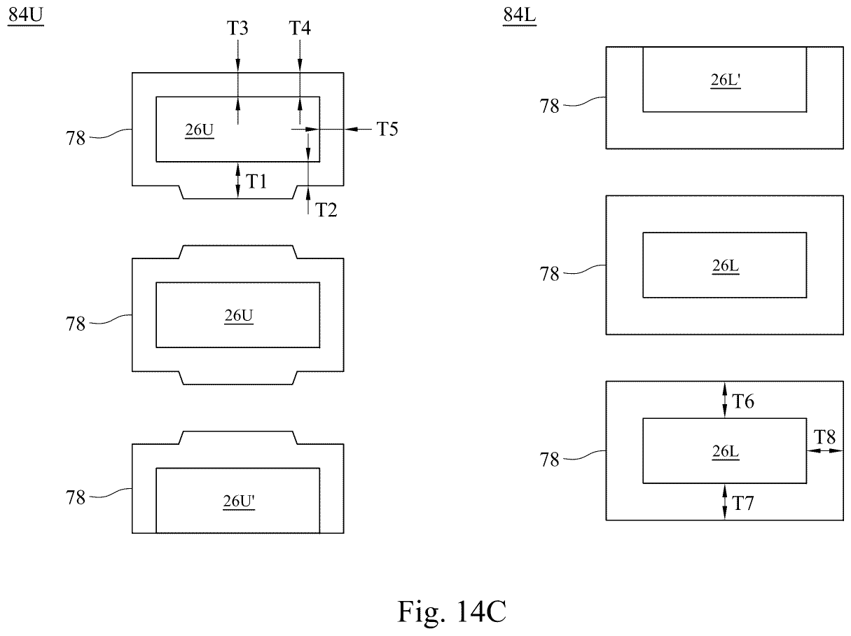

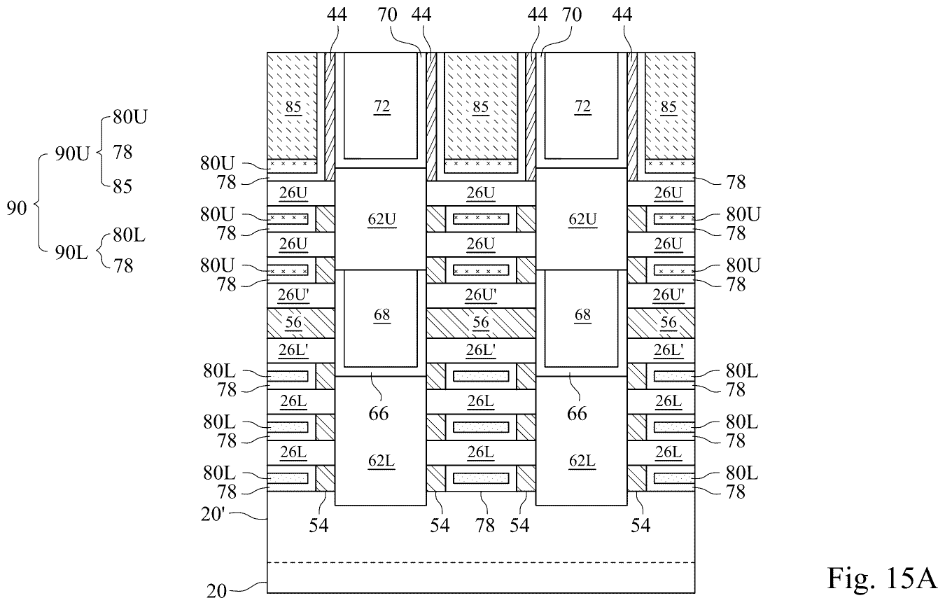

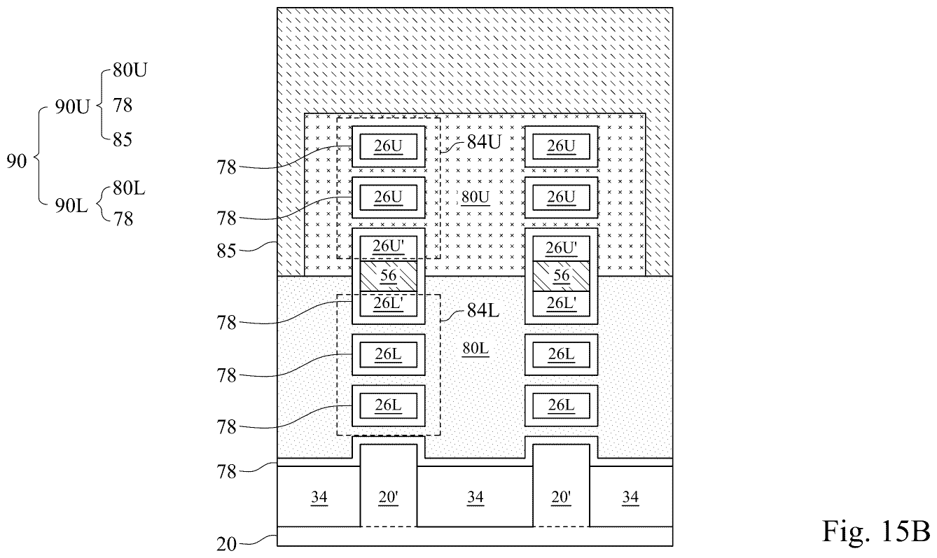

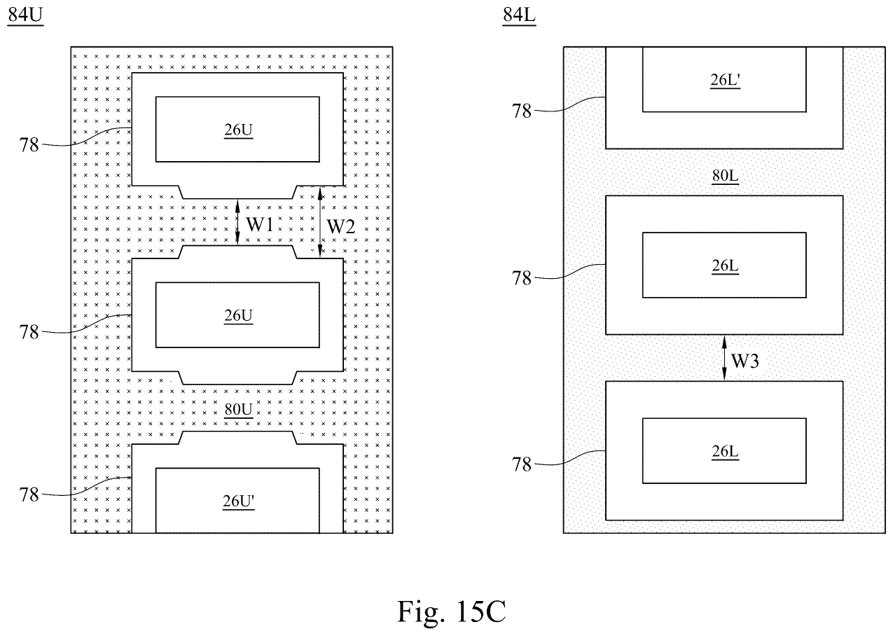

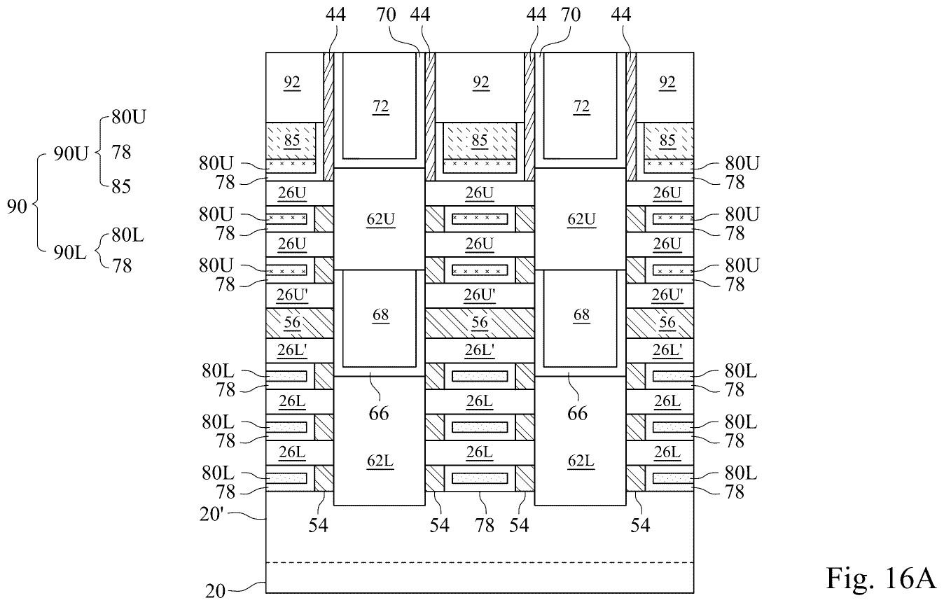

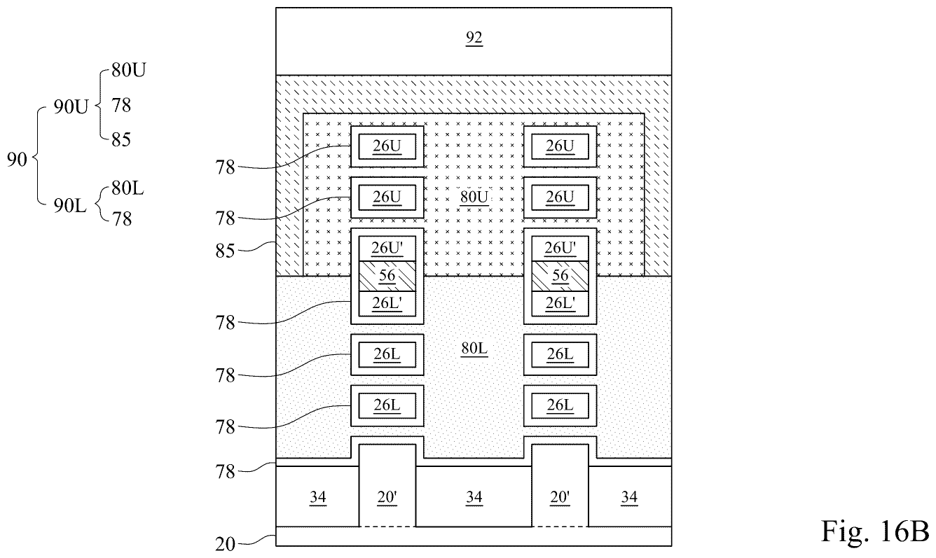

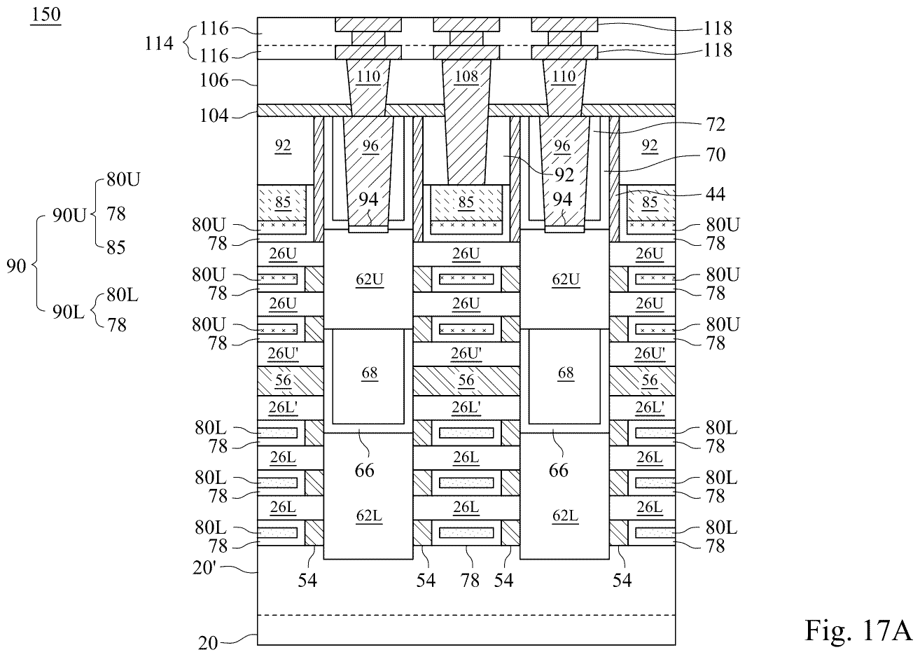

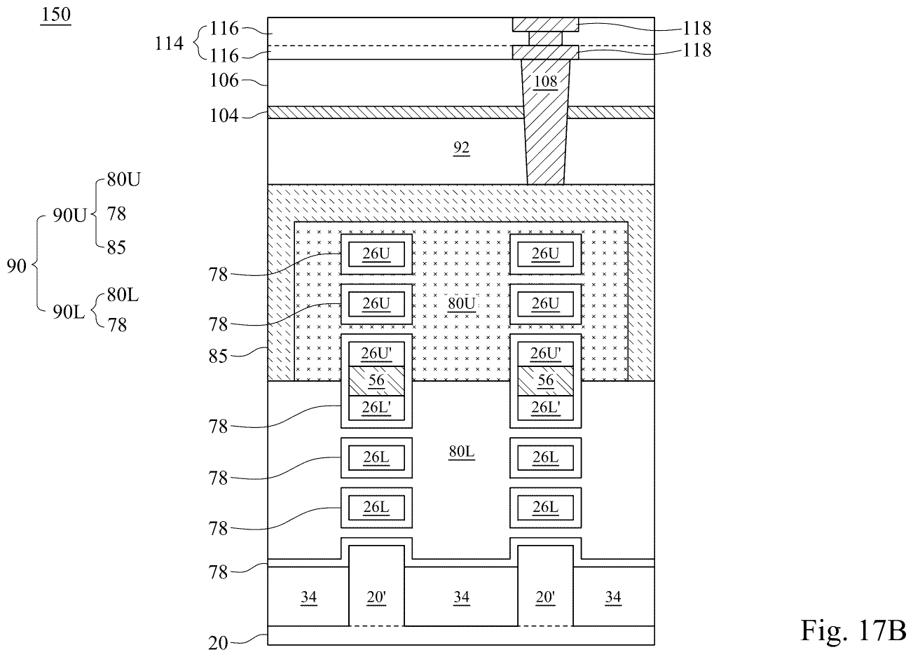

In FIGS. 6A and 6B, the mask 40 and the dummy gate stacks 42 are removed. The cross-sectional view in FIG. 6A may correspond to the cross-sectional view shown in FIG. 5A and the cross-sectional view in FIG. 6B may correspond to the cross-sectional view shown in FIG. 5B. The mask 40 may be removed by a suitable etching process. The dummy gate stacks 42 may be removed by one or more suitable etching processes. In some embodiments, the dummy gate layers 38 and the dummy dielectric layers 36 are removed by one or more anisotropic dry etching processes. The etching process(es) may use etchants that selectively etch the dummy gate layers 38 and the dummy dielectric layers 36 while the gate spacers 44, the second CESLs 70, and second ILDs 72 may remain substantially intact during the etching process(es).

In FIGS. 7A and 7B, the dummy nanostructures 24A are removed. The cross-sectional view in FIG. 7A may correspond to the cross-sectional view shown in FIG. 6A and the cross-sectional view in FIG. 7B may correspond to the cross-sectional view shown in FIG. 6B. The dummy nanostructures 24A may be removed by a suitable etching process. The etching process may selectively remove the dummy nanostructures 24A while the semiconductor fins 20′ and the semiconductor nanostructures 26 may remain substantially intact during the etching process. Exposed corners of the semiconductor fins 20′ and the semiconductor nanostructures 26 shown in FIG. 7B may rounded after the etching process. In the embodiments where the dummy nanostructures 24A comprise silicon germanium, and the semiconductor nanostructures 26 comprise silicon, the etching process may be a wet isotropic etching process and etchants such as tetramethylammonium hydroxide, ammonium hydroxide, or the like may be used.

In FIGS. 8A and 8B, gate dielectric layers 78 are formed on exposed surfaces of the semiconductor nanostructures 26 and protective layers 77 are formed on the gate dielectric layers 78. The protective layers 77 may be subsequently partially removed and remaining portions of the protective layers 77 may reduce a risk of damaging the gate dielectric layers 78 during subsequent etching processes as described in greater detail below. The cross-sectional view in FIG. 8A may correspond to the cross-sectional view shown in FIG. 7A and the cross-sectional view in FIG. 8B may correspond to the cross-sectional view shown in FIG. 7B.

The gate dielectric layers 78 may be formed on the exposed surfaces the semiconductor nanostructures 26, the semiconductor fins 20', the STI regions 34, the inner spacers 54, and the gate spacers 44. The gate dielectric layers 78 may wrap around the semiconductor nanostructures 26 as shown in FIG. 8B. The gate dielectric layers 78 may be on exposed top surfaces, bottom surfaces, and sidewalls of the semiconductor nanostructures 26. The protective layers 77 may wrap around the gate dielectric layers 78 that are in contact with the semiconductor nanostructures 26 as shown in FIG. 8B. The protective layers 77 may be on top surfaces, bottom surfaces, and sidewalls of the gate dielectric layers 78 that in contact with the semiconductor nanostructures 26. The protective layers 77 may fill up spaces between neighboring semiconductor nanostructures 26 over a same semiconductor fin 20′.

The gate dielectric layers 78 may comprise a material with a dielectric constant (k-value) greater than about 7.0, which may be referred to as a high-k material. The high-k material may be an oxide, such as silicon oxide, metal oxide, or the like; a silicate, such as metal silicate, or the like; combinations thereof, or the like. The metal oxide may be oxide of hafnium, aluminum, zirconium, lanthanum, manganese, barium, titanium, lead, combinations thereof, or the like. The metal silicate may be silicate of hafnium, aluminum, zirconium, lanthanum, manganese, barium, titanium, lead, combinations thereof, or the like. The gate dielectric layers 78 may be formed by a suitable deposition process, such as molecular-beam deposition (MBD), ALD, PECVD, or the like. Then a suitable etching process may be performed to remove portions of the gate dielectric layers 78 above the second ILDs 72. Single-layered gate dielectric layers 78 are shown in FIGS. 8A and 8B as an example, the gate dielectric layers 78 may include multiple layers.

The protective layers 77 may comprise a dielectric material with a high etching selectivity to the material of the gate dielectric layers 78, such as silicon oxide, aluminum oxide, titanium oxide, tantalum oxide, or the like. The protective layers 77 may be formed by a suitable deposition process, such as ALD, PECVD, or the like. The protective layers 77 may cover surfaces of the gate dielectric layers 78, the gate spacers 44, the second CESLs 70, and the second ILDs 72.

In FIGS. 9A and 9B, sacrificial layers 79 are formed on lower portions of the protective layers 77. The cross-sectional view in FIG. 9A may correspond to the cross-sectional view shown in FIG. 8A and the cross-sectional view in FIG. 9B may correspond to the cross-sectional view shown in FIG. 8B. The sacrificial layers 79 may protect portions of the protective layers 77 that are in contact with the sacrificial layers 79 during subsequent etching processes. Top surfaces of the sacrificial layers 79 may be below top surfaces of the dielectric isolation layers 56 and above bottom surfaces of the dielectric isolation layers 56. The sacrificial layers 79 may comprises a silicon-containing dielectric material, such as silicon oxide, silicon nitride, silicon carbide, silicon oxynitride, silicon oxycarbide, silicon carbonitride, or the like. The sacrificial layers 79 may be formed by a suitable deposition process, such as ALD, PECVD, or the like. Then a suitable etching process may be performed to remove portions of the sacrificial layers 79 on upper portions of the protective layers 77.

In FIGS. 10A and 10B, the protective layers 77 are partially removed. The cross-sectional view in FIG. 10A may correspond to the cross-sectional view shown in FIG. 9A and the cross-sectional view in FIG. 10B may correspond to the cross-sectional view shown in FIG. 9B. After the partial removal, the protective layers 77 may remain between neighboring upper semiconductor nanostructures 26U and 26U′, and on top surfaces and bottom surfaces of the gate dielectric layers 78 that are in contact with the upper semiconductor nanostructures 26U and 26U′. Recesses 81 may be formed between sidewalls of the protective layers 77 and sidewalls of the upper semiconductor nanostructures 26U and 26U′. The recesses 81 may expose portions of the top surfaces and the bottom surfaces of the gate dielectric layers 78 that are in contact with the upper semiconductor nanostructures 26U and 26U′. Portions of the protective layers 77 that are covered by the sacrificial layers 79 may also be partially removed and top surfaces of the lower portions of the protective layers 77 may be below the top surfaces of the sacrificial layers 79 after the partial removal. FIG. 10B shows the top surfaces of the lower portions of the protective layers 77 being substantially flat as an example. In other embodiments, the lower portions of the protective layers 77 are convex.

The protective layers 77 may be partially removed by a suitable etching process, such as a dry etching process. During the etching process, the material of the protective layers 77 is removed at a rate significantly higher than the materials of the gate dielectric layers 78. During the etching process, portions of the gate dielectric layers 78 that are exposed to the etchant may be slightly etched and portions of the gate dielectric layers 78 that remain covered by the protective layers 77 may be substantially intact.

In FIG. 10C, the sacrificial layers 79 are removed. The cross-sectional view in FIG. 10C may correspond to the cross-sectional view shown in FIG. 10A. The sacrificial layers 79 may be removed by a suitable etching process, such as a wet etching process using solutions comprising strong oxidizing agents and acidic chemicals or alkaline chemicals or the like as the etchant. During the etching process, portions of the gate dielectric layers 78 that are exposed to the etchant may be slightly etched and portions of the gate dielectric layers 78 that are covered by the protective layers 77 may be substantially intact. The etching selectivity between the protective layers 77 and the gate dielectric layers 78 may be higher than the etching selectivity between the sacrificial layers 79 and the gate dielectric layers 78.

In FIG. 10D, a material layer 83′ is formed over the structure shown in FIG. 10C. The cross-sectional view in FIG. 10D may correspond to the cross-sectional view shown in FIG. 10A. The material layer 83′ may fill in the recesses 81. The material layer 83′ may comprise a same conductive material as subsequently formed lower gate electrode layers 80L, such as titanium nitride, or the like. The material layer 83′ may be formed by a suitable deposition process, such as ALD, PECVD, or the like.

In FIGS. 11A and 11B, protective layers 83 are formed by removing portions of the material layer 83′ (shown in FIG. 10D). The cross-sectional view in FIG. 11A may correspond to the cross-sectional view shown in FIG. 10A and the cross-sectional view in FIG. 11B may correspond to the cross-sectional view shown in FIG. 10B. The protective layers 83 may protect the protective layers 77 and the gate dielectric layers 78 that are in contact with the protective layers 83 during subsequent etching processes. The portions of the material layer 83′ may be removed by a suitable etching process. During the etching process, portions of the gate dielectric layers 78 that are exposed to the etchant may be slightly etched and portions of the gate dielectric layers 78 that are covered by the protective layers 77 and the protective layers 83 may be substantially intact.

The protective layers 77 and the protective layers 83 may occupy spaces between the neighboring upper semiconductor nanostructures 26U and 26U′, which may prevent a material of the lower gate electrodes from being formed between the neighboring upper semiconductor nanostructures 26U and 26U′ in a subsequent process. As a result, the length of another subsequent process that recesses the lower gate electrodes may be shortened and a risk of having residual material of the lower gate electrodes between the neighboring upper semiconductor nanostructures 26U and 26U′ after recessing the lower gate electrodes may be reduced.

In FIGS. 12A and 12B, the protective layers 77 below the dielectric isolation layers 56 are removed and the lower gate electrode layers 80L are formed on exposed surfaces of the gate dielectric layers 78. The cross-sectional view in FIG. 12A may correspond to the cross-sectional view shown in FIG. 11A and the cross-sectional view in FIG. 12B may correspond to the cross-sectional view shown in FIG. 11B. The protective layers 77 below the dielectric isolation layers 56 may be removed by a suitable etching process, such as an etching process similar to the etching process described with respect to FIGS. 10A and 10B. During the etching process, the material of the protective layers 77 is removed at a rate significantly higher than the material of the gate dielectric layers 78. During the etching process, portions of the gate dielectric layers 78 that are exposed to the etchant may be slightly etched and portions of the gate dielectric layers 78 that are covered by the protective layers 77 and the protective layers 83 may be substantially intact.

The lower gate electrode layers 80L may be then formed on the exposed surfaces of the gate dielectric layers 78 and sidewalls of the protective layers 83. The lower gate electrode layers 80L may wrap around the lower semiconductor nanostructures 26L and 26L′ and fill in spaces between neighboring lower semiconductor nanostructures 26L and 26L′, and between the lower semiconductor nanostructures 26L and the semiconductor fins 20′. Single-layered lower gate electrode layers 80L are shown in FIGS. 12A and 12B as an example, the lower gate electrode layers 80L may include multiple layers. The lower gate electrode layers 80L may be formed by one or more suitable deposition processes, such as PVD, CVD, or the like.

The lower gate electrode layers 80L may be formed of material(s) that are suitable for the device type of the lower nanostructure-FETs. For example, the lower gate electrode layers 80L may include one or more work function tuning layer(s) formed of material(s) that are suitable for the device type of the lower nanostructure-FETs. In some embodiments, the lower gate electrode layers 80L include n-type work function tuning layers, which may be formed of titanium aluminum, titanium aluminum nitride, titanium aluminum carbide, tantalum aluminum, tantalum carbide, combinations thereof, or the like. In some embodiments, the lower gate electrode layers 80L include p-type work function tuning layers, which may be formed of titanium nitride, tantalum nitride, tungsten nitride, molybdenum nitride, combinations thereof, or the like.

In FIGS. 13A and 13B, the lower gate electrode layers 80L are recessed and the protective layers 83 are removed. The lower gate electrode layers 80L and the gate dielectric layers 78 in contact with the lower gate electrode layers 80L may be collectively referred to as the lower gate structure 90L, and the lower semiconductor nanostructures 26L may be referred to as the lower channel regions. The cross-sectional view in FIG. 13A may correspond to the cross-sectional view shown in FIG. 12A and the cross-sectional view in FIG. 13B may correspond to the cross-sectional view shown in FIG. 12B. A top surface of the recessed lower gate electrode layers 80L may be below the top surfaces of the dielectric isolation layers 56. Surfaces of the gate dielectric layers 78 on the upper semiconductor nanostructures 26U and 26U′ that are not covered by the protective layers 77 may be exposed after the lower gate electrode layers 80L are recessed. Sidewalls of the protective layers 77 may be exposed after the protective layers 83 are removed. The lower gate electrode layers 80L may be recessed by a suitable etching process, such as a wet etching process using solutions comprising strong oxidizing agents and acidic chemicals or alkaline chemicals or the like as the etchant. The protective layers 83 may be removed by the same etching process. The etching selectivity between the protective layers 77 and the gate dielectric layers 78 may be higher than the etching selectivity between lower gate electrode layers 80L and the gate dielectric layers 78.

During the etching process, portions of the gate dielectric layers 78 that are exposed to the etchant may be slightly etched and portions of the gate dielectric layers 78 that are covered by the protective layers 77 may be substantially intact. Due to the protective layers 77, the gate dielectric layers 78 between the neighboring upper semiconductor nanostructures 26U and 26U′ are protected during the etching process and a length of the etching process may be shortened since the protective layers 77 prevented the material of the lower gate electrode layers 80L from forming between the neighboring upper semiconductor nanostructures 26U and 26U′, which may reduce a risk of damaging other portions of the gate dielectric layers 78. Therefore, the risk of damaging the gate dielectric layers 78 during the etching process may be reduced. Also, since the protective layers 77 prevented the material of the lower gate electrode layers 80L from forming between the neighboring upper semiconductor nanostructures 26U and 26U′, a risk of having residual material of the lower gate electrode layers 80L between the neighboring upper semiconductor nanostructures 26U and 26U′ after the etching process may be reduced. As a result, the performance and reliability of the subsequently formed stacking transistor device may be improved.

In some embodiments, isolation layers (not illustrated) are formed on the lower gate electrode layers 80L. The isolation layers may act as an isolation feature between the lower gate electrode layers 80L and a subsequently formed upper gate electrode over the lower gate electrode layers 80L. The isolation layers may be formed by depositing a dielectric layer (e.g., silicon oxide, silicon nitride, silicon oxynitride, silicon oxycarbonitride, combinations thereof, or the like) and subsequently recessing the dielectric layer to expose the gate dielectric layers 78 on the upper semiconductor nanostructures 26U and 26U′.

In FIGS. 14A through 14B, the protective layers 77 between the neighboring upper semiconductor nanostructures 26U and 26U′ are removed. The cross-sectional view in FIG. 14A may correspond to the cross-sectional view shown in FIG. 13A and the cross-sectional view in FIG. 14B may correspond to the cross-sectional view shown in FIG. 13B. The protective layers 77 between the neighboring upper semiconductor nanostructures 26U and 26U′ may be removed by a suitable etching process, such as an etching process similar to the etching process described with respect to FIGS. 10A and 10B. During the etching process, the material of the protective layers 77 is removed at a rate significantly higher than the material of the gate dielectric layers 78. After the etching process, the portions of the gate dielectric layers 78 between the neighboring upper semiconductor nanostructures 26U and 26U′ are exposed.

FIG. 14C shows detailed views of a region 84U and a region 84L in FIG. 14B. In the region 84U, the upper semiconductor nanostructures 26U and 26U′, and the gate dielectric layers 78 on the upper semiconductor nanostructures 26U and 26U′ are shown. Portions of the gate dielectric layer 78 that were protected by (e.g., in contact with) the protective layers 77 and the protective layers 83 during the etching processes described with respect to FIGS. 11A through 14B may be referred to as protected portions. The protected portions may include portions of the gate dielectric layer 78 between the neighboring upper semiconductor nanostructures 26U and 26U′. The protected portions may have protrusions and uneven surfaces (e.g., protruding surfaces). Portions of the gate dielectric layer 78 that were not protected by (e.g., not in contact with) the protective layers 77 or the protective layers 83 during the etching processes described with respect to FIGS. 11A through 14B may be referred to as unprotected portions. The unprotected portions may include portions of the gate dielectric layer 78 on sidewalls of the upper semiconductor nanostructures 26U and 26U′, and a portion of the gate dielectric layer 78 on a top surface of the upper semiconductor nanostructure 26U at a top of the multi-layer stack 22 (shown in FIG. 5B). The unprotected portions may have even surfaces (e.g., substantially flat surfaces).

The protected portions may have a thickness T1 adjacent center lines of the upper semiconductor nanostructures 26U and 26U′. The thickness T1 may be in a range from about 1 nm to about 2 nm. The protected portions may have a thickness T2 adjacent the sidewalls of the upper semiconductor nanostructures 26U and 26U′. The thickness T2 may be in a range from about 1 nm to about 2 nm. The thickness T1 may be larger than the thickness T2. The unprotected portion on the top surface of the upper semiconductor nanostructure 26U may have a thickness T3 adjacent the center line of the upper semiconductor nanostructure 26U. The thickness T3 may be in a range from about 1 nm to about 2 nm. The unprotected portion on the top surface of the upper semiconductor nanostructure 26U may have a thickness T4 adjacent the sidewall of the upper semiconductor nanostructure 26U. The thickness T4 may be in a range from about 1 nm to about 2 nm. The thickness T3 may equal the thickness T4. The unprotected portions on the sidewalls of the upper semiconductor nanostructures 26U and 26U′ may have a thickness T5. The thickness T5 may be in a range from about 1 nm to about 2 nm. The thickness T1 and the thickness T2 may be larger than the thickness T3, the thickness T4, and the thickness T5.

In the region 84L, the lower semiconductor nanostructures 26L and 26L′ and the gate dielectric layers 78 on the lower semiconductor nanostructures 26L and 26L′ are shown. Portions of the gate dielectric layer 78 between the neighboring lower semiconductor nanostructures 26L and a portion of the gate dielectric layer 78 on a bottom surface of the lower semiconductor nanostructure 26L may have even surfaces. Portions of the gate dielectric layer 78 on sidewalls of the lower semiconductor nanostructures 26L and 26L′ may have even surfaces. The portions of the gate dielectric layer 78 between the neighboring lower semiconductor nanostructures 26L and 26L′ may have a thickness T6 in a range from about 1 nm to about 2 nm. The portion of the gate dielectric layer 78 on the bottom surface of the lower semiconductor nanostructure 26L may have a thickness T7 in a range from about 1 nm to about 2 nm. The thickness T6 and the thickness T7 may equal the thickness T1. The portions of the gate dielectric layer 78 on sidewalls of the lower semiconductor nanostructures 26L and 26L′ may have a thickness T8 in a range from about 1 nm to about 2 nm. The thickness T8 may be larger than the thickness T5.

In FIGS. 15A through 15B, upper gate electrode layers 80U are formed over the lower gate electrode layers 80L and on exposed surfaces of the gate dielectric layers 78, and a fill layer 85 is formed over the upper gate electrode layers 80U. The upper gate electrode layers 80U, the gate dielectric layers 78 in contact with the upper gate electrode layers 80U, and the fill layer 85 may be collectively referred to as the upper gate structure 90U, and the upper semiconductor nanostructures 26U may be referred to as the upper channel regions. The lower gate structure 90L and the upper gate structure 90U may be collectively referred to as the gate structure 90. The cross-sectional view in FIG. 15A may correspond to the cross-sectional view shown in FIG. 14A and the cross-sectional view in FIG. 15B may correspond to the cross-sectional view shown in FIG. 14B.

The upper gate electrode layers 80U may wrap around the upper semiconductor nanostructures 26U and 26U′, and fill in spaces between the neighboring upper semiconductor nanostructures 26U and 26U′. The fill layer 85 may be on top surface and sidewalls of the upper gate electrode layers 80U, and the top surface of the lower gate electrode layers 80L. Single-layered upper gate electrode layers 80U are shown in FIGS. 15A and 15B as an example, the upper gate electrode layers 80U may include multiple layers. The upper gate electrode layers 80U may be formed by one or more of suitable deposition processes, such as PVD, CVD, or the like. Then the fill layer 85 may be formed by a suitable deposition process, such as PVD, CVD, or the like, or a suitable plating process.

The upper gate electrode layers 80U may be formed of material(s) that are suitable for the device type of the upper nanostructure-FETs. For example, the lower gate electrode layers 80L may include one or more work function tuning layer(s) formed of material(s) that are suitable for the device type of the lower nanostructure-FETs of the stacking transistor device. In some embodiments, the upper gate electrode layers 80U include n-type work function tuning layers, which may be formed of titanium aluminum, titanium aluminum nitride, titanium aluminum carbide, tantalum aluminum, tantalum carbide, combinations thereof, or the like. In some embodiments, the upper gate electrode layers 80U include p-type work function tuning layers, which may be formed of titanium nitride, tantalum nitride, tungsten nitride, molybdenum nitride, combinations thereof, or the like. The fill layer 136 may be formed of a conductive material, such as aluminum, tungsten, cobalt, copper, or the like.

FIG. 15C shows detailed views of the region 84U and the region 84L in FIG. 15B. In the region 84U, the upper semiconductor nanostructures 26U and 26U′, the gate dielectric layers 78 on the upper semiconductor nanostructures 26U and 26U′, and the upper gate electrode layers 80U are shown. Portions of the upper gate electrode layers 80U between neighboring protected portions of the gate dielectric layers 78 may have a width W1 adjacent the center lines of the upper semiconductor nanostructures 26U and 26U′. The width W1 may be in a range from about 4 nm to about 8 nm. Portions of the upper gate electrode layers 80U between the neighboring protected portions of the gate dielectric layers 78 may have a width W2 adjacent the sidewalls of the upper semiconductor nanostructures 26U and 26U′. The width W2 may be in a range from about 4 nm to about 8 nm. The width W2 may be larger than the width W1. In the region 84L, the lower semiconductor nanostructures 26L and 26L′, the gate dielectric layers 78 on the lower semiconductor nanostructures 26L and 26L′, and the lower gate electrode layers 80L are shown. Portions of the upper gate electrode layers 80U between the neighboring gate dielectric layers 78 may have a width W3. The width W3 may be in a range from about 4 nm to about 8 nm. The width W3 may equal the width W1.

In FIGS. 16A through 16B, gate masks 92 may be formed on the upper gate structures 90U. The cross-sectional view in FIG. 16A may correspond to the cross-sectional view shown in FIG. 15A and the cross-sectional view in FIG. 16B may correspond to the cross-sectional view shown in FIG. 15B. The gate masks 92 may be formed by recessing the upper gate structures 90U, filling the resulting recesses with a dielectric material such as silicon nitride, silicon carbonitride, silicon oxynitride, silicon oxycarbonitride, or the like, and performing a planarization process, such as CMP or the like, to remove the excess portions of the dielectric material over the second ILDs 72. After the planarization process, the top surfaces of the gate masks 92, the gate dielectric layers 78, the second ILDs 72, and the gate spacers 44 may be substantially coplanar (within process variations).

In FIGS. 17A through 17B, metal-semiconductor alloy regions 94 and source/drain contacts 96 are formed through the second ILD 72 to electrically couple to the upper epitaxial source/drain regions 62U and/or the lower epitaxial source/drain regions 62L. The cross-sectional view in FIG. 17A may correspond to the cross-sectional view shown in FIG. 16A and the cross-sectional view in FIG. 17B may correspond to the cross-sectional view shown in FIG. 16B. FIGS. 17A and 17B are cross-sectional views of a same structure, which may be referred to as a stacking transistor device 150.

As an example to form the source/drain contacts 96, openings are formed through the second ILDs 72 and the second CESLs 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILDs 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

A third CESL 104 and a third ILD 106 are then formed. In some embodiments, the third CESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrode layers 80U and the source/drain contacts 96, respectively. As an example to form the gate contacts 108 and the source/drain vias 110, openings for the gate contacts 108 and the source/drain vias 110 are formed through the third ILD 106 and the third CESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the third ILD 106. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate structures 90L and the lower epitaxial source/drain regions 62L may be made through a backside of the substrate 20 (e.g., a side opposite to the front-side interconnect structure 114).

The embodiments of the present disclosure have some advantageous features. Due to the protective layers 77, the risk of damaging portions of the gate dielectric layers 78 during recessing the lower gate electrode layers 80L and the risk of having residual material of the lower gate electrode layers 80L between the neighboring upper semiconductor nanostructures 26U and 26U′ after recessing the lower gate electrode layers 80L may be reduced. As a result, the performance and reliability of the stacking transistor device 150 may be improved.

In an embodiment, a semiconductor device includes a first epitaxial source/drain region, wherein the first epitaxial source/drain region is doped with a dopant, wherein the first epitaxial source/drain region includes a first portion and a second portion, wherein the first portion has a first concentration of the dopant, and wherein the second portion has a second concentration of the dopant different from the first concentration of the dopant; a first nanostructure on a sidewall of the first epitaxial source/drain region and in contact with the first portion of the first epitaxial source/drain region, wherein the second portion of the first epitaxial source/drain region is spaced apart from the first nanostructure by the first portion of the first epitaxial source/drain region; and a first gate structure around the first nanostructure in a cross-sectional view, the first gate structure includes: a first dielectric layer around the first nanostructure in the cross-sectional view, wherein a first portion of the first dielectric layer is on a top surface of the first nanostructure, wherein the first portion of the first dielectric layer includes a substantially flat top surface in the cross-sectional view, wherein a second portion of the first dielectric layer is on a bottom surface of the first nanostructure, and wherein the second portion of the first dielectric layer includes a protruding bottom surface in the cross-sectional view; and a first gate electrode around the first dielectric layer in the cross-sectional view. In an embodiment, the second portion of the first dielectric layer has a first thickness adjacent a center line of the first nanostructure in the cross-sectional view, wherein the second portion of the first dielectric layer has a second thickness adjacent a first sidewall of the first nanostructure in the cross-sectional view, and wherein the first thickness is larger than the second thickness. In an embodiment, the first portion of the first dielectric layer has a third thickness adjacent the center line of the first nanostructure in the cross-sectional view, and wherein the first thickness is larger than the third thickness. In an embodiment, the first portion of the first dielectric layer has a third thickness adjacent the first sidewall of the first nanostructure in the cross-sectional view, and wherein the second thickness is larger than the third thickness. In an embodiment, a third portion of the first dielectric layer is on the first sidewall of the first nanostructure, wherein the third portion of the first dielectric layer has a third thickness in the cross-sectional view, and wherein the second thickness is larger than the third thickness. In an embodiment, the semiconductor device further includes a second nanostructure on the sidewall of the first epitaxial source/drain region, wherein the second nanostructure is underneath the first nanostructure, wherein the first gate structure is around the second nanostructure in the cross-sectional view, wherein the first gate structure further includes a second dielectric layer around the second nanostructure in the cross-sectional view, wherein a first portion of the second dielectric layer is on a top surface of the second nanostructure, wherein the first portion of the second dielectric layer includes a protruding top surface in the cross-sectional view, wherein a second portion of the second dielectric layer is on a bottom surface of the second nanostructure, and wherein the second portion of the second dielectric layer includes a protruding bottom surface in the cross-sectional view. In an embodiment, the semiconductor device includes a second nanostructure underneath the first nanostructure; and a second gate structure around the second nanostructure in the cross-sectional view, the second gate structure includes: a second dielectric layer around the second nanostructure in the cross-sectional view, wherein a first portion of the second dielectric layer is on a top surface of the second nanostructure, wherein the first portion of the second dielectric layer includes a substantially flat top surface in the cross-sectional view, wherein a second portion of the first dielectric layer is on a bottom surface of the second nanostructure, and wherein the second portion of the second dielectric layer includes a substantially flat bottom surface in the cross-sectional view; and a second gate electrode around the second dielectric layer in the cross-sectional view.

In an embodiment, a method of forming a semiconductor device includes forming a first nanostructure over a semiconductor fin and a second nanostructure over the first nanostructure; growing a first epitaxial structure, wherein the first nanostructure and the second nanostructure interface with the first epitaxial structure, wherein the first epitaxial structure is doped with a dopant, wherein the first epitaxial structure includes a first portion adjacent the first nanostructure and a second portion away from the first nanostructure, wherein the first portion has a first concentration of the dopant, and wherein the second portion has a second concentration of the dopant different from the first concentration of the dopant; forming a first etch stop layer over the first epitaxial structure; forming a first dielectric layer over the first etch stop layer; depositing a first gate dielectric layer around the first nanostructure and a second gate dielectric layer around the second nanostructure in a cross-sectional view, wherein the first gate dielectric layer and the second gate dielectric layer include a first material; forming a first protective layer between the first gate dielectric layer and the second gate dielectric layer, wherein the first protective layer includes a second material; removing the first protective layer by an etching process, wherein a second etching rate of the second material is higher than a first etching rate of the first material during the etching process; and forming a first gate electrode around the first gate dielectric layer and the second gate dielectric layer in the cross-sectional view. In an embodiment, the second gate dielectric layer includes a first portion on a top surface of the second nanostructure and a second portion on a bottom surface of the second nanostructure, wherein the first portion includes an even top surface in the cross-sectional view after removing the first protective layer, and wherein the second portion includes an uneven bottom surface in the cross-sectional view after removing the first protective layer. In an embodiment, a first thickness of the first portion is smaller than a second thickness of the second portion. In an embodiment, the second material is silicon oxide, aluminum oxide, titanium oxide, or tantalum oxide. In an embodiment, the method further includes forming a second gate electrode over the semiconductor fin after forming the first protective layer, wherein a first portion of the second gate electrode is on sidewalls of the first gate dielectric layer and the second gate dielectric layer; and removing the first portion of the second gate electrode to expose the sidewalls of the first gate dielectric layer and the second gate dielectric layer before removing the first protective layer. In an embodiment, the first gate electrode is over a remaining portion of the second gate electrode, and wherein the first gate electrode and the second gate electrode include different materials. In an embodiment, the method of claim includes forming second protective layers on sidewalls of the first protective layer before forming the second gate electrode, wherein the second protective layers and the second gate electrode include a same material; and removing the second protective layers during removing the first portion of the second gate electrode.

In an embodiment, a method of forming a semiconductor device includes forming a first nanostructure and a second nanostructure over a semiconductor fin, wherein the first nanostructure is between the second nanostructure and the semiconductor fin; depositing a first gate dielectric layer around the first nanostructure and a second gate dielectric layer around the second nanostructure in a cross-sectional view, wherein the first gate dielectric layer and the second gate dielectric layer include a first material; forming a first protective layer on a bottom surface of the first gate dielectric layer and a second protective layer on a bottom surface of the second gate dielectric layer, wherein the first protective layer and the second protective layer include a second material different from the first material; removing the first protective layer; forming a first gate electrode around the first gate dielectric layer in the cross-sectional view; removing the second protective layer; and forming a second gate electrode around the second gate dielectric layer in the cross-sectional view. In an embodiment, the first gate dielectric layer has an even bottom surface in the cross-sectional view after removing the first protective layer, and wherein the second gate dielectric layer has an uneven bottom surface in the cross-sectional view after removing the second protective layer. In an embodiment, the first protective layer is around the first gate dielectric layer in the cross-sectional view, and wherein sidewalls of the second protective layer are recessed from sidewalls of the second gate dielectric layer. In an embodiment, the method further includes forming third protective layers on sidewalls of the second protective layer before removing the first protective layer. In an embodiment, the method further includes simultaneously removing a portion of the first gate electrode on sidewalls of the second gate dielectric layer and the third protective layers before removing the second protective layer. In an embodiment, the method further includes forming an isolation structure between the first nanostructure and the second nanostructure; and forming a third gate dielectric layer on sidewalls of the isolation structure in the cross-sectional view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first epitaxial source/drain region, wherein the first epitaxial source/drain region is doped with a dopant, wherein the first epitaxial source/drain region comprises a first portion and a second portion, wherein the first portion has a first concentration of the dopant, and wherein the second portion has a second concentration of the dopant different from the first concentration of the dopant;
a first nanostructure on a sidewall of the first epitaxial source/drain region and in contact with the first portion of the first epitaxial source/drain region, wherein the second portion of the first epitaxial source/drain region is spaced apart from the first nanostructure by the first portion of the first epitaxial source/drain region; and
a first gate structure around the first nanostructure in a cross-sectional view, the first gate structure comprises:
a first dielectric layer around the first nanostructure in the cross-sectional view, wherein a first portion of the first dielectric layer is on a top surface of the first nanostructure, wherein the first portion of the first dielectric layer comprises a substantially flat top surface in the cross-sectional view, wherein a second portion of the first dielectric layer is on a bottom surface of the first nanostructure, and wherein the second portion of the first dielectric layer comprises a protruding bottom surface in the cross-sectional view; and
a first gate electrode around the first dielectric layer in the cross-sectional view.

2. The semiconductor device of claim 1, wherein the second portion of the first dielectric layer has a first thickness adjacent a center line of the first nanostructure in the cross-sectional view, wherein the second portion of the first dielectric layer has a second thickness adjacent a first sidewall of the first nanostructure in the cross-sectional view, and wherein the first thickness is larger than the second thickness.

3. The semiconductor device of claim 2, wherein the first portion of the first dielectric layer has a third thickness adjacent the center line of the first nanostructure in the cross-sectional view, and wherein the first thickness is larger than the third thickness.

4. The semiconductor device of claim 2, wherein the first portion of the first dielectric layer has a third thickness adjacent the first sidewall of the first nanostructure in the cross-sectional view, and wherein the second thickness is larger than the third thickness.

5. The semiconductor device of claim 2, wherein a third portion of the first dielectric layer is on the first sidewall of the first nanostructure, wherein the third portion of the first dielectric layer has a third thickness in the cross-sectional view, and wherein the second thickness is larger than the third thickness.

6. The semiconductor device of claim 1, further comprising a second nanostructure on the sidewall of the first epitaxial source/drain region, wherein the second nanostructure is underneath the first nanostructure, wherein the first gate structure is around the second nanostructure in the cross-sectional view, wherein the first gate structure further comprises a second dielectric layer around the second nanostructure in the cross-sectional view, wherein a first portion of the second dielectric layer is on a top surface of the second nanostructure, wherein the first portion of the second dielectric layer comprises a protruding top surface in the cross-sectional view, wherein a second portion of the second dielectric layer is on a bottom surface of the second nanostructure, and wherein the second portion of the second dielectric layer comprises a protruding bottom surface in the cross-sectional view.

7. The semiconductor device of claim 1, further comprising:
a second nanostructure underneath the first nanostructure; and
a second gate structure around the second nanostructure in the cross-sectional view, the second gate structure comprises:
a second dielectric layer around the second nanostructure in the cross-sectional view, wherein a first portion of the second dielectric layer is on a top surface of the second nanostructure, wherein the first portion of the second dielectric layer comprises a substantially flat top surface in the cross-sectional view, wherein a second portion of the first dielectric layer is on a bottom surface of the second nanostructure, and wherein the second portion of the second dielectric layer comprises a substantially flat bottom surface in the cross-sectional view; and
a second gate electrode around the second dielectric layer in the cross-sectional view.

8. A method of forming a semiconductor device, the method comprising:
forming a first nanostructure over a semiconductor fin and a second nanostructure over the first nanostructure;
growing a first epitaxial structure, wherein the first nanostructure and the second nanostructure interface with the first epitaxial structure, wherein the first epitaxial structure is doped with a dopant, wherein the first epitaxial structure comprises a first portion adjacent the first nanostructure and a second portion away from the first nanostructure, wherein the first portion has a first concentration of the dopant, and wherein the second portion has a second concentration of the dopant different from the first concentration of the dopant;
forming a first etch stop layer over the first epitaxial structure;
forming a first dielectric layer over the first etch stop layer;
depositing a first gate dielectric layer around the first nanostructure and a second gate dielectric layer around the second nanostructure in a cross-sectional view, wherein the first gate dielectric layer and the second gate dielectric layer comprise a first material;
forming a first protective layer between the first gate dielectric layer and the second gate dielectric layer, wherein the first protective layer comprises a second material;
removing the first protective layer by an etching process, wherein a second etching rate of the second material is higher than a first etching rate of the first material during the etching process; and
forming a first gate electrode around the first gate dielectric layer and the second gate dielectric layer in the cross-sectional view.

9. The method of claim 8, wherein the second gate dielectric layer comprises a first portion on a top surface of the second nanostructure and a second portion on a bottom surface of the second nanostructure, wherein the first portion comprises an even top surface in the cross-sectional view after removing the first protective layer, and wherein the second portion comprises an uneven bottom surface in the cross-sectional view after removing the first protective layer.

10. The method of claim 9, wherein a first thickness of the first portion is smaller than a second thickness of the second portion.

11. The method of claim 8, wherein the second material is silicon oxide, aluminum oxide, titanium oxide, or tantalum oxide.

12. The method of claim 8, further comprising:
forming a second gate electrode over the semiconductor fin after forming the first protective layer, wherein a first portion of the second gate electrode is on sidewalls of the first gate dielectric layer and the second gate dielectric layer; and
removing the first portion of the second gate electrode to expose the sidewalls of the first gate dielectric layer and the second gate dielectric layer before removing the first protective layer.

13. The method of claim 12, wherein the first gate electrode is over a remaining portion of the second gate electrode, and wherein the first gate electrode and the second gate electrode comprise different materials.

14. The method of claim 12, further comprising:
forming second protective layers on sidewalls of the first protective layer before forming the second gate electrode, wherein the second protective layers and the second gate electrode comprise a same material; and
removing the second protective layers during removing the first portion of the second gate electrode.

15. A method of forming a semiconductor device, the method comprising:
forming a first nanostructure and a second nanostructure over a semiconductor fin, wherein the first nanostructure is between the second nanostructure and the semiconductor fin;
depositing a first gate dielectric layer around the first nanostructure and a second gate dielectric layer around the second nanostructure in a cross-sectional view, wherein the first gate dielectric layer and the second gate dielectric layer comprise a first material;
forming a first protective layer on a bottom surface of the first gate dielectric layer and a second protective layer on a bottom surface of the second gate dielectric layer, wherein the first protective layer and the second protective layer comprise a second material different from the first material;
removing the first protective layer;
forming a first gate electrode around the first gate dielectric layer in the cross-sectional view;
removing the second protective layer; and
forming a second gate electrode around the second gate dielectric layer in the cross-sectional view.

16. The method of claim 15, wherein the first gate dielectric layer has an even bottom surface in the cross-sectional view after removing the first protective layer, and wherein the second gate dielectric layer has an uneven bottom surface in the cross-sectional view after removing the second protective layer.

17. The method of claim 15, wherein the first protective layer is around the first gate dielectric layer in the cross-sectional view, and wherein sidewalls of the second protective layer are recessed from sidewalls of the second gate dielectric layer.

18. The method of claim 17, further comprising forming third protective layers on sidewalls of the second protective layer before removing the first protective layer.

19. The method of claim 18, further comprising simultaneously removing a portion of the first gate electrode on sidewalls of the second gate dielectric layer and the third protective layers before removing the second protective layer.

20. The method of claim 15, further comprising:
forming an isolation structure between the first nanostructure and the second nanostructure; and
forming a third gate dielectric layer on sidewalls of the isolation structure in the cross-sectional view.
